(19) United States
(12) Patent Application Publication
(10) Pub. No.: US 2012/0043454 A1
(43) Pub. Date: Feb. 23, 2012

(54) SAMPLING AND HOLDING CIRCUIT, METHOD OF DRIVING THE SAME AND IMAGING APPARATUS

(75) Inventor: Takamasa Sakuragi, Machida-shi (JP)

(73) Assignee: CANON KABUSHIKI KAISHA, Tokyo (JP)

(21) Appl. No.: 13/205,836

(22) Filed: Aug. 9, 2011

(30) Foreign Application Priority Data
Aug. 20, 2010 (JP) 2010-185421

(51) Int. Cl. G11C 27/02; G01J 1/44

(52) U.S. Cl. 250/206; 327/94; 327/95

(57) ABSTRACT

A sampling and holding circuit includes an amplifier (A) that amplifies a signal, a holding capacitor (Ch) that stores the signal, and a switch (S) connected between an output terminal of the amplifier and the holding capacitor. In a state in which the switch is on, the amplifier amplifies the signal with a first signal bandwidth, and subsequently, in a state in which the switch is on, the amplifier amplifies the signal with a second signal bandwidth, which is narrower than the first signal bandwidth, and subsequently the switch is turned off while the amplifier still amplifies the signal with the second signal bandwidth.

### BACKGROUND OF THE INVENTION

1. Field of the Invention

The present invention relates to a sampling and holding circuit, a method of driving the circuits and an imaging apparatus.

2. Description of the Related Art

Japanese Patent Application Laid-Open No. 2006-345280 discloses a double sampling circuit used in an image sensor. In most recent analog signal processing circuits, a sampling and holding circuit using a switch and a capacitor is used. There is a demand for high speed operation not only in imaging sensors, but also in almost all electronic apparatuses, requiring a sampling and holding circuit in a signal processing circuit to operate at high speed. In order for a sampling and holding circuit to operate at high speed, it is necessary to broaden a signal bandwidth of a buffer that drives an input terminal of the sampling and holding circuit. Ordinarily, a signal bandwidth of a buffer, which depends on the bias current thereof, becomes broader as its bias current becomes larger.

### SUMMARY OF THE INVENTION

However, a gain of a buffer depends on its bias current, and thus, the bandwidth becomes broader as its bias current becomes larger. Accordingly, an increase of the bias current of the buffer to provide a broader bandwidth in an attempt to increase the speed of the sampling and holding circuit operation results in an increase of noise at an output terminal of the buffer.

According to the present invention, a sampling and holding circuit comprises: an amplifier for amplifying a signal; a holding capacitor for storing the signal; and a switch connected between the amplifier and the holding capacitor, wherein the amplifier amplifies the signal with a first signal bandwidth under a state in which the switch is on, thereafter the amplifier amplifies the signal with a second signal bandwidth under the state in which the switch is on, the second bandwidth being narrower than the first signal bandwidth, and thereafter the switch is turned off while the amplifier maintains the second signal bandwidth.

Further features of the present invention will become apparent from the following description of exemplary embodiments with reference to the attached drawings.

### BRIEF DESCRIPTION OF THE DRAWINGS

FIG. 1 is a diagram illustrating a schematic configuration of a sampling and holding circuit according to a first embodiment.

FIG. 2 is a timing diagram of the sampling and holding circuit according to the first embodiment.

FIG. 3 is a diagram illustrating a schematic configuration of a sampling and holding circuit according to a second embodiment.

FIG. 4 is a timing diagram illustrating the sampling and holding circuit according to the second embodiment.

FIG. 5 is a diagram illustrating an example circuit of a buffer amplifier.

FIG. 6 is a graph indicating a voltage gain-frequency characteristic of a buffer amplifier.

FIG. 7 is a circuit diagram of a buffer amplifier according to a third embodiment.

FIG. 8 is a diagram illustrating a schematic configuration of a buffer amplifier according to a fourth embodiment.

FIG. 9 is a graph indicating a gain-frequency characteristic of the buffer amplifier according to the fourth embodiment.

FIG. 10 is a diagram illustrating a specific example of a variable current source.

FIG. 11 is a diagram illustrating a specific example of a variable resistor according to the second embodiment.

FIG. 12 is a diagram illustrating an example configuration of a sampling and holding circuit according to the fourth embodiment.

FIG. 13 is a timing diagram for the sampling and holding circuit in FIG. 12.

FIG. 14 is a diagram illustrating an example configuration of an imaging apparatus according to a fifth embodiment.

FIG. 15 is a timing diagram for the imaging apparatus in FIG. 14.

FIG. 16 is a diagram illustrating an example configuration of an imaging apparatus according to a sixth embodiment.

FIG. 17 is a timing diagram illustrating the imaging apparatus in FIG. 16.

### DESCRIPTION OF THE EMBODIMENTS

Preferred embodiments of the present invention will now be described in detail in accordance with the accompanying drawings.

### First Embodiment

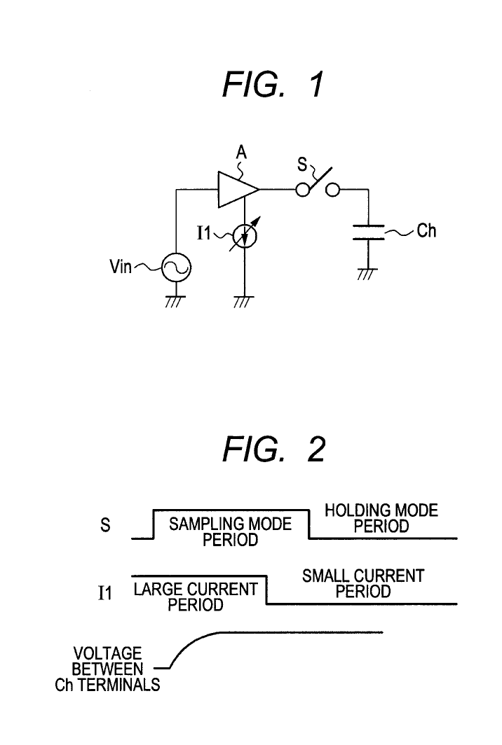

FIG. 1 is a diagram illustrating an example configuration of a sampling and holding circuit according to a first embodiment, and FIG. 2 is a timing diagram for the sampling and holding circuit. The Figures illustrate a buffer amplifier A that drives an input of a sampling and holding circuit including a switch S and a holding capacitor Ch, a bias current source I1 of a bias current for the buffer amplifier A, and a signal source Vin of a signal applied to an input of the buffer amplifier A. The buffer amplifier A amplifies the signal from the signal source Vin. The holding capacitor Ch stores the signal. The switch S is connected between an output terminal of the buffer amplifier A and the holding capacitor Ch.

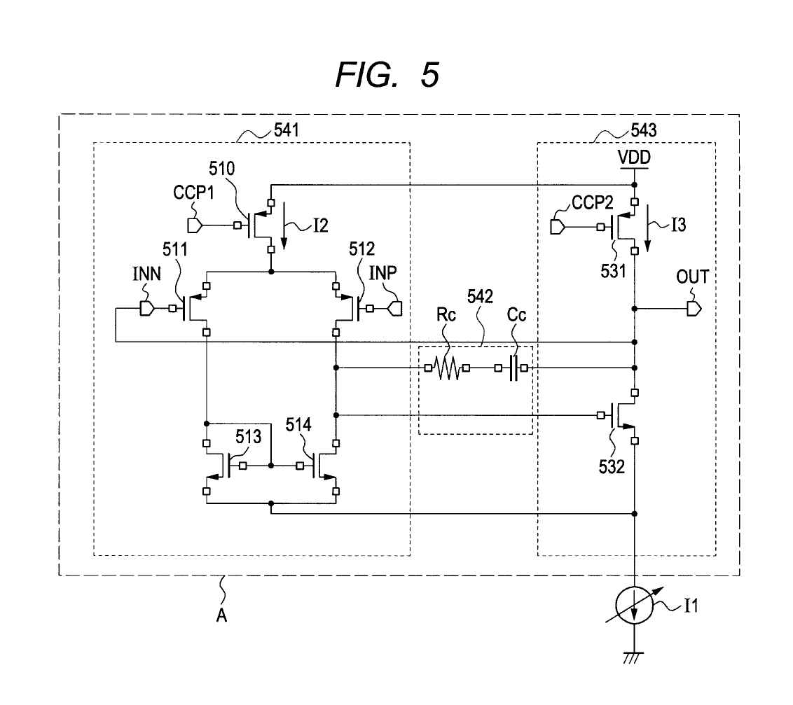

FIG. 5 is a diagram illustrating an example configuration of the buffer amplifier A and the current source I1. The buffer amplifier A is a negative feedback circuit including a differential amplifier circuit 541, a common source amplifier circuit 543, and a phase compensating circuit 542 for oscillation prevention. An inverting input terminal INN of the differential amplifier circuit 541 is connected to an output terminal OUT of the common source amplifier circuit 543. The differential amplifier circuit 541 includes an MOS field-effect transistor (MOS transistor) 510 in which a bias current I2 is controlled by means of a voltage input from a terminal CCP1, and MOS transistors from 511 to 514. In the differential amplifier circuit 541, the terminal INN is an inverting input terminal and a terminal INP is a non-inverting input terminal. The phase compensating circuit 542, which includes a circuit of serial connection of a resistor Rc and a capacitor Cc, is connected between the differential amplifier circuit 541 and the common source amplifier circuit 543. The common source amplifier circuit 543 includes an MOS transistor 531 in which a bias current I3 is controlled by means of a voltage input from a terminal CCP2, and an MOS transistor 532. The buffer amplifier A amplifies a signal from the signal source Vin, which is input from the input terminal INP, and outputs the signal from an output terminal OUT.

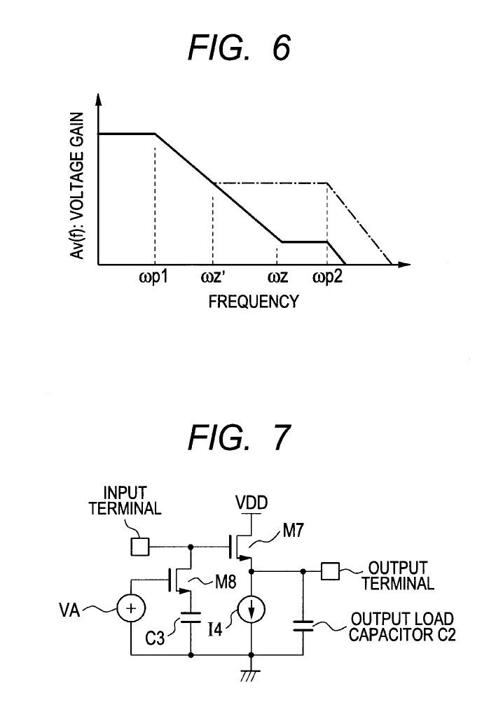

FIG. 6 is a graph illustrating a voltage gain-frequency characteristic of the buffer amplifier A in FIG. 5. The graph indicates a zero ωz, a first pole frequency ωp1 and a second pole frequency ωp2. The first pole frequency ωp1 is roughly represented by expression (1) below.

ωp1=1/(gm×R1×RL×Cc) (1)

Here, gm is a mutual conductance of the MOS transistor 532, and R1 and RL are an output impedance and an output load resistance of the differential amplifier circuit 541, respectively.

The output impedance R1 is equal to a drain resistance Rds of the MOS transistors 512 and 514 arranged in parallel, and the drain resistance Rds is inversely proportional to the drain current Id (Rds∝1/Id). Meanwhile, gm has a relationship of gm∝√Id.

Furthermore, the drain current Id is equal to ½ of the bias current I2, and consequently, the first pole frequency ωp1 is represented by ωp1∝√I2/Cc, and is proportional to the square root of the bias current I2. For frequency equal or higher than the first pole frequency ωp1 the voltage gain changes at a rate of −6 db/oct, and thus, as illustrated in FIG. 6, the first pole frequency ωp1 basically determines the bandwidth. Accordingly, the bandwidth is proportional to the square root of the bias current I2. Furthermore, the second pole frequency ωp2 and the zero ωz can be represented by expressions (2) and (3) below. Here, C2 is a load capacitor of the output terminal.

ωp2≈−gm/C2 (2)

ωz≈−1/{Cc(1/gm−Rc)} (3)

According to expression (3), the frequency ωz changes depending on the value of the resistor Rc, and where Rc>>1/gm, the frequency ωz has a small value (ωz′), the buffer amplifier A exhibits the gain characteristic indicated by the dashed-dotted line in FIG. 6. The gain for a high-frequency region increases, allowing provision of a boarder bandwidth. Meanwhile, a decrease in the value of the resistor Rc results in provision of a narrower bandwidth.

Random noise Vo(f) (f stands for frequency) at the output terminal of the buffer amplifier A can be represented by expression (4) below. Here, V1(f) is an input referred noise voltage of the buffer amplifier A, V2(f) is a noise voltage of a signal from the signal source Vin, which is applied to the input terminal of the buffer amplifier A, and Av(f) is a voltage gain of the buffer amplifier A.

Vo(f)=Av(f)×√(V1(f)²+V2(f)²) (4)

As illustrated in FIG. 6, Av(f) indicates that the voltage gain is a function of a frequency f. Since noise at the output terminal can be represented by expression (5) below, as the buffer amplifier A has a broader bandwidth, noise output from the buffer amplifier A becomes larger.

∫Vo(f)df=∫{Av(f)×√{(V1(f)²+V2(f)²)}df (5)

In the present embodiment, the current source I1 is connected between the buffer amplifier A and a ground potential node, and a current thereof is variable according to timings of a sampling mode and a holding mode. A specific example of the variable current source I1 is illustrated in FIG. 10. The variable current source I1 includes constant current sources 110 and I11, switches S10 and S11 and MOS transistors M10 and M11. Gates of the MOS transistors M10 and M11 are connected to each other, forming a current mirror circuit.

An operation of the current source I1 will be described with reference to the timing diagram in FIG. 2. In the large current period in the current source I1, both the switches S10 and S11 in FIG. 10 are turned on, thereby currents from the constant current sources 110 and I11 flowing into a drain terminal of the MOS transistor M10. As described above, the MOS transistors M10 and M11 form a current mirror circuit, and thus, a drain current of the MOS transistor M11 has a value obtained by adding up the currents from the current sources I10 and I11. Then in the small current period of the current source I1 in FIG. 2, the switch S10 in FIG. 10 is turned off while the switch S11 being turned on, thereby the current from the current source I11 flowing into the drain of the MOS transistor M10. Thus, the drain current of the MOS transistor M11 is also the current from the current source I11.

In FIG. 1, when the switch S is turned on and the sampling and holding circuit is thereby made to enter a sampling mode, responding to the voltage of the signal source Vin, the buffer amplifier A charges the holding capacitor Ch, a voltage between terminals of the holding capacitor Ch changes. An increase in the speed of the change leads to an increase in the operation speed of the sampling and holding circuit, and thus, it is necessary that the buffer amplifier A has a broad signal bandwidth. Thus, a current from the bias current source I1 for the buffer amplifier A is set to have a large value during the time of the voltage between the terminals of the capacitor Ch varying. After the end of transition of the voltage between the terminals of the capacitor Ch, the current from the bias current source I1 for the buffer amplifier A is set to have a small value, the buffer amplifier A is made to have a narrow-bandwidth, low-noise mode, whereby the signal voltage stored in the capacitor Ch also includes low noise. A duration for setting the current from the bias current source I1 to be a large current after turning the switch S on, thereby making the sampling and holding circuit enter the sampling mode can be determined with reference to settling-time for a maximum value of an amplitude of a signal handled by the buffer amplifier A loaded with the capacitor Ch.

As described above, in a state in which the switch S is on (in the sampling mode), the buffer amplifier A amplifies the signal in a first signal bandwidth (board bandwidth). Subsequently, in a state in which the switch S is on (in the sampling mode), the buffer amplifier A amplifies the signal in a second signal bandwidth (narrow bandwidth), which is narrower than the first signal bandwidth (broad bandwidth). Subsequently, in a state in which the switch S is off (in the holding mode), the buffer amplifier A amplifies the signal in the second signal bandwidth (narrow bandwidth). The buffer amplifier A amplifies the signal in the first signal bandwidth (board bandwidth) by being supplied with a first bias current, and amplifies the signal in the second signal bandwidth (narrow bandwidth) by being supplied with a second bias current, which is smaller than the first bias current.

The signal source Vin is an input signal source of the buffer amplifier A that drives the input terminal of the sampling and holding circuit. The signal from the signal source Vin changes, and an output of the buffer amplifier A changes in response to the change, thereby turning the sampling and holding switch S on, resulting in the output voltage being applied to the sampling and holding capacitor Ch. During that period, the current from the bias current source I1 for the buffer amplifier A is set to have a large value so that the buffer amplifier A enters a high-speed driving mode, and after the end of the transition of the output voltage of the buffer amplifier A, the current from the bias current source I1 of the buffer amplifier A is set to have a small value so that the buffer amplifier A enters a low-speed, low-noise mode. Subsequently, the sampling and holding switch S is turned off to enter a holding state. As a result, both a speed increase and a noise decrease can be provided in the sampling and holding circuit.

### Second Embodiment

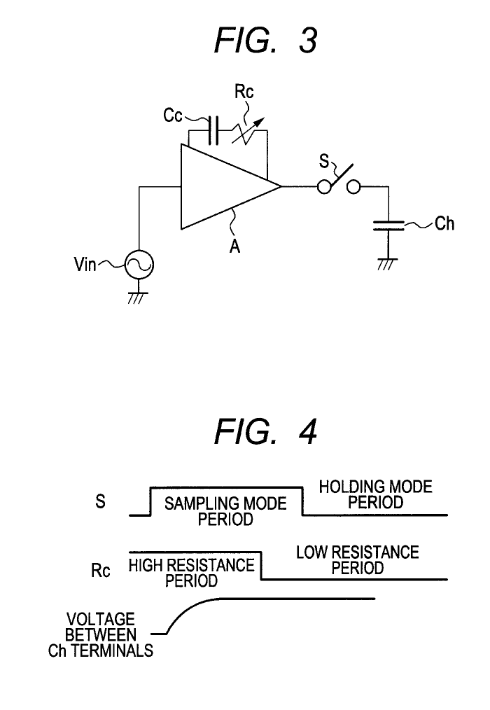

FIG. 3 is a diagram illustrating an example configuration of a sampling and holding circuit according to a second embodiment. Although the present embodiment is similar to the embodiment in FIG. 1, the present embodiment is different from the embodiment in FIG. 1 in that a variable resistor Rc whose resistance is variable according to timings of a sampling mode or a holding mode is connected in series to a phase compensation capacitor (or a capacitor for band limitation) Cc included in a buffer amplifier A and the current source I1 is deleted. A buffer amplifier A is a negative feedback circuit including a phase compensating circuit 542 (FIG. 5) including a circuit of serial connection of a capacitor Cc and a variable resistor Rc. During a certain period in which the sampling and holding circuit is in the sampling mode where a switch S is on as illustrated in the timing diagram in FIG. 4, the resistor Rc is set to have a high value to make the buffer amplifier A enter a board bandwidth, high-speed mode. Subsequently, at a point of time of end of transition of a voltage between terminals of a capacitor Ch, the resistor Rc is set to have a low value to make the buffer amplifier A enter a narrow bandwidth, low-noise mode. The above-described circuit operation enables the sampling and holding circuit to perform a high-speed, low-noise operation. As described above, the variable resistor Rc is made to have a first resistance value (high resistance) to amplify a signal with a first signal bandwidth (board bandwidth), while the variable resistor Rc is made to have a second resistance value (low resistance), which is lower than the first resistance (high resistance), to amplify the signal with the second signal bandwidth (narrow bandwidth).

The signal input to the buffer amplifier A that drives an input terminal of the sampling and holding circuit, changes, and an output of the buffer amplifier A changes in response to the change, thereby turning the sampling and holding switch S on, resulting in the output voltage being applied to the sampling and holding capacitor Ch. During that period, the resistor Rc connected in series to the phase compensation capacitor Cc in the buffer amplifier A is set to have a high value so that the buffer amplifier A enters a high-speed driving mode. Subsequently, after end of the transition of the output voltage of the buffer amplifier A, the resistor Rc connected in series to the phase compensation capacitor Cc in the buffer amplifier A is set to have a low value so that the buffer amplifier A enters a low-speed, low-noise mode. As a result, both a speed increase and a noise decrease can be provided in the sampling and holding circuit.

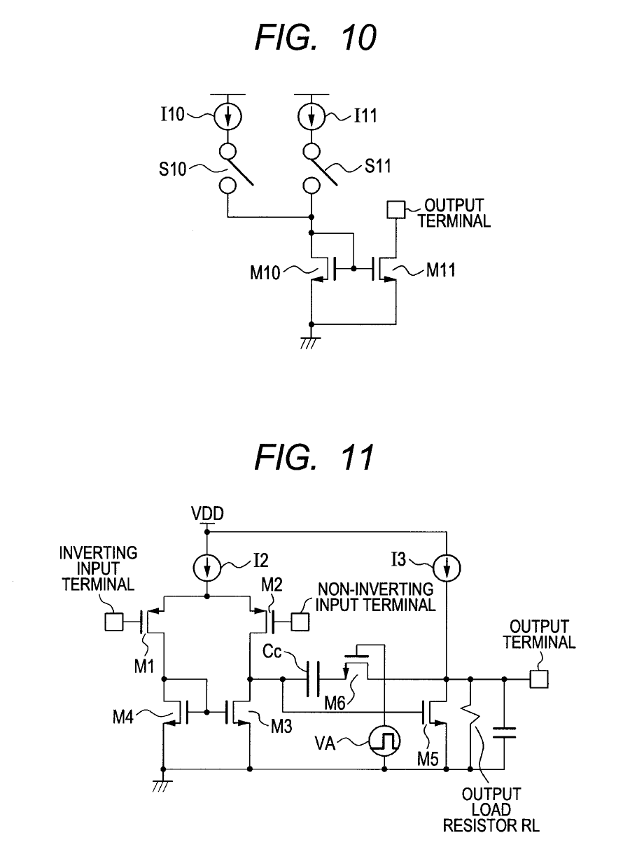

FIG. 11 is a specific example of the buffer amplifier A where the resistor Rc is variable. A current source I2 corresponds to the MOS transistor 510 in FIG. 5, and a current source I3 corresponds to the MOS transistor 531 in FIG. 5. An MOS transistor M1 corresponds to the MOS transistor 511 in FIG. 5, and an MOS transistor M2 corresponds to the MOS transistor 512 in FIG. 5. An MOS transistor M3 corresponds to the MOS transistor 514 in FIG. 5, and an MOS transistor M4 corresponds to the MOS transistor 513 in FIG. 5. An MOS transistor M6 corresponds to the resistor Rc in FIG. 5, and an MOS transistor M5 corresponds to the MOS transistor 532 in FIG. 5. The variable resistor Rc equivalent to a resistance between a drain and a source of the MOS transistor M6, whose resistive value changes according to a gate voltage of the MOS transistor M6. Description will be given with reference to the timing diagram in FIG. 4. During a large resistance period of the resistor Rc in FIG. 4, a pulse voltage source VA in FIG. 11 is set to have a value of a certain low voltage VL, thereby the voltage between the gate and the source of the MOS transistor M6 has a low value, and consequently, the on-resistance Rc of the re-channel MOS transistor M6 has a certain high value. Accordingly, as described above for the bandwidth of the buffer amplifier A in FIG. 5, the buffer amplifier A has a boarder bandwidth and may operate at higher speed. During a low-resistance period of the resistor Rc in FIG. 4, the pulse voltage source VA in FIG. 11 is set to have a value of a certain high voltage VH, thereby the voltage between the gate and the source of the MOS transistor M6 has a certain high value, while the on-resistance Rc of the re-channel MOS transistor M6 has a certain low value. Accordingly, for a reason similar to the above, the signal bandwidth of the buffer amplifier A becomes narrow. For the variable resistor Rc, a plurality of switches and a resistor connected in series to each of the plurality of switches may be used so that the resistance value is changed by performing on/off control of the plurality of switches.

### Third Embodiment

FIG. 7 is a diagram illustrating an example configuration of a buffer amplifier A according to a third embodiment. The buffer amplifier A according to the present embodiment is provided in place of the buffer amplifier A and the current source I1 in FIG. 1. This is a case where the buffer amplifier A is an NMOS source follower amplifier, not an operational amplifier to which negative feedback is applied. First, a brief description will be given with reference to FIG. 7. The Figure illustrates an MOS transistor M7, which provides a source follower amplifier, a bias current source 14 for the MOS transistor M7, an output load capacitor C2, an MOS transistor M8, a voltage source VA that drives a gate of the MOS transistor M8, and a capacitor C3.

Where an MOS source follower amplifier is used as a drive circuit that drives a sampling and holding circuit, a pole frequency ωp in a gain-frequency characteristic of the MOS source follower amplifier can be represented by expression (6) below, and is proportional to a mutual conductance gm of the MOS transistor M7. Here, the mutual conductance gm can be represented by expression (7) below.

ωp=gm/C2 (6)

gm=√(2k×Id×W/L) (7)

Here, Id is a drain current, k is a constant, W and L are a gate width and a gate length of the MOS transistor, respectively, and thus, as the drain current Id is larger, the pole ωp is larger, that is, a boarder bandwidth is provided.

According to the present embodiment, processing similar to the processing described above for the amplifier circuit using negative feedback is performed. A signal input to a source follower amplifier that drives an input terminal of the sampling and holding circuit, changes, and an output of the source follower amplifier changes in response to the change, thereby turning the sampling and holding switch S on, resulting in the output voltage being applied to a sampling and holding capacitor Ch. During that period, a current from a bias current source I4 for the source follower amplifier is set to have a large value so that the buffer amplifier A enters a high-speed driving mode. Then, after end of the transition of the output voltage of the source follower amplifier, the current from the bias current source I4 of the source follower amplifier is set to have a small value so that the buffer amplifier A enters a low-speed, low-noise mode. Subsequently, the sampling and holding switch S is turned off to enter a holding state. As a result, both a speed increase and a noise decrease can be provided in the sampling and holding circuit. For a specific example of the variable current source I4, the one described above with reference to FIG. 10 can be used. When the current from the bias current source I4 is set to have a large value, both switches S10 and S11 in FIG. 10 are turned on to make a drain current of an MOS transistor M11 included in a current mirror circuit have a value of I10+I11. When the current from the bias current source I4 is set to have a small value, only the switch S10 in FIG. 10 is turned on while the switch S11 being off, the drain current of the MOS transistor M11 included in the current mirror circuit has a value of I10.

### Fourth Embodiment

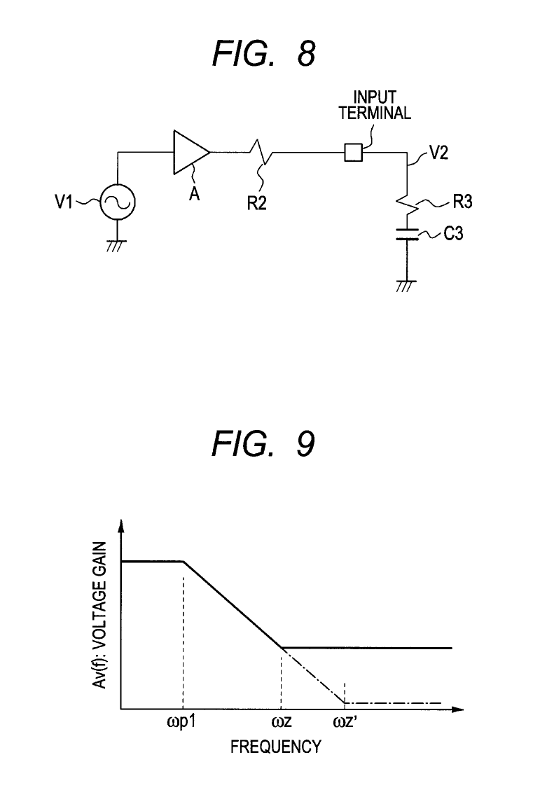

FIG. 8 is a diagram illustrating a buffer amplifier according to a fourth embodiment. In the present embodiment, use of an MOS transistor M8 in FIG. 7, a voltage source VA that drives a gate of the MOS transistor M8, and a capacitor C3 enables control of a bandwidth of the source follower amplifier. In such a manner as described above, a signal bandwidth of a source follower amplifier is changed before a timing of turning a switch S for a sampling and holding circuit off from an on-state, enabling provision of both a speed increase and a noise decrease in the sampling and holding circuit.

For description of the matter described above, the principle of the present embodiment will be described in detail with reference to FIG. 8. FIG. 8 illustrates a drive circuit (assuming that a voltage gain=1) A that drives an input portion of the source follower amplifier, an output resistor R2 for the drive circuit, and an on-resistance R3 of the MOS transistor M8 in FIG. 7. A signal source V1 corresponds to the signal source Vin in FIG. 1. A ratio (voltage gain) between the signal source V1 and a voltage V2 appearing at the input portion of the source follower amplifier via the resistor R2 can be represented by expression (8) below.

V2/V1=(1+ωC3×R3)/{(R2+R3)×ωC3+1} (8)

Where there is a relationship of R3>>R2, V2/V1≈1. However, where R3<<R2, the relationship represented by expression (9) below will be provided. FIG. 9 indicates the relationship in a Bode diagram.

V2/V1≈(1+ωC3×R3)/(R2×ωC3+1) (9)

In the Figure, ωp1 is a pole frequency, ωz is a zero. The pole frequency ωp1 and the zero ωz can be represented by expressions (10) and (11), respectively.

ωp1=1/(C3×R2) (10)

ωz=1/(C3×R3) (11)

When a value of the resistance R3 is changed, a point of the zero is changed from ωz to ωz′ in FIG. 9, and thus, it can be understood that as the value of the resistance R3 is larger, a broader bandwidth is provided.

When the voltage value of the voltage source VA that drives the gate of the MOS transistor M8 in FIG. 7 is changed, the on-resistance of the MOS transistor M8 changes, resulting in change in the aforementioned signal bandwidth. Accordingly, it can be understood that the voltage of the voltage source VA is controlled before a timing of turning the switch S in the sampling and holding circuit off from an on-state, enabling provision of both a speed increase and a noise decrease in the sampling and holding circuit.

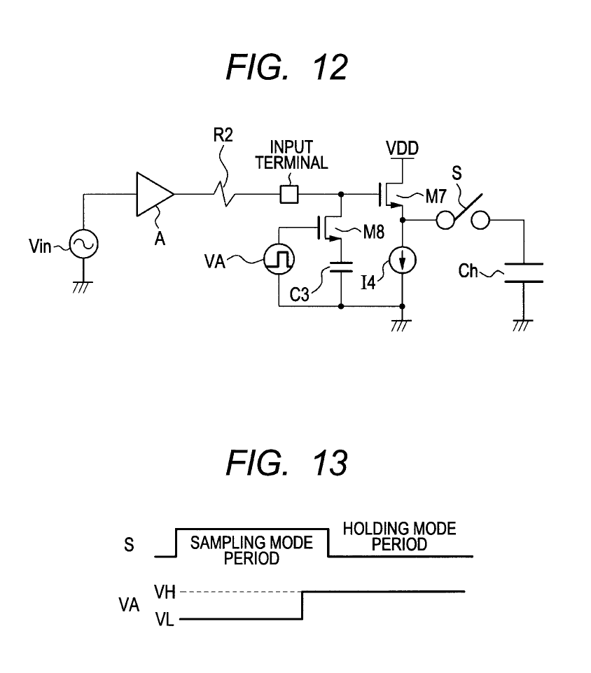

FIG. 12 is a diagram illustrating an example configuration of the sampling and holding circuit according to the present embodiment, which is a specific example of a sampling and holding circuit including a variable voltage source VA whose voltage is changed according to an operation mode of the sampling and holding circuit. FIG. 13 is a timing diagram of the sampling and holding circuit in FIG. 12. Reference numerals in the Figures correspond to those in FIGS. 7 and 8. When a switch S in FIG. 12 is turned on, thereby the sampling and holding circuit entering a sampling mode, a voltage of the voltage source VA is set to be a certain low potential VL. Since the voltage is applied to the gate of the MOS transistor M8 in FIG. 12, the on-resistance R3 of the n-channel MOS transistor M8 has a certain high value. For the aforementioned reason, the zero-point frequency ωz has a low value, and thus, the source follower amplifier in the MOS transistor M7 has a board bandwidth.

As illustrated in FIG. 13, before the switch S in FIG. 12 being turned off, thereby the sampling and holding circuit entering a holding mode, the voltage of the voltage source VA in FIG. 12 is set to be a certain high value VH. Consequently, the value of the on-resistance R3 of the MOS transistor M8 becomes a certain low value, resulting in the source follower amplifier in the MOS transistor M7 having a narrow bandwidth.

### Fifth Embodiment

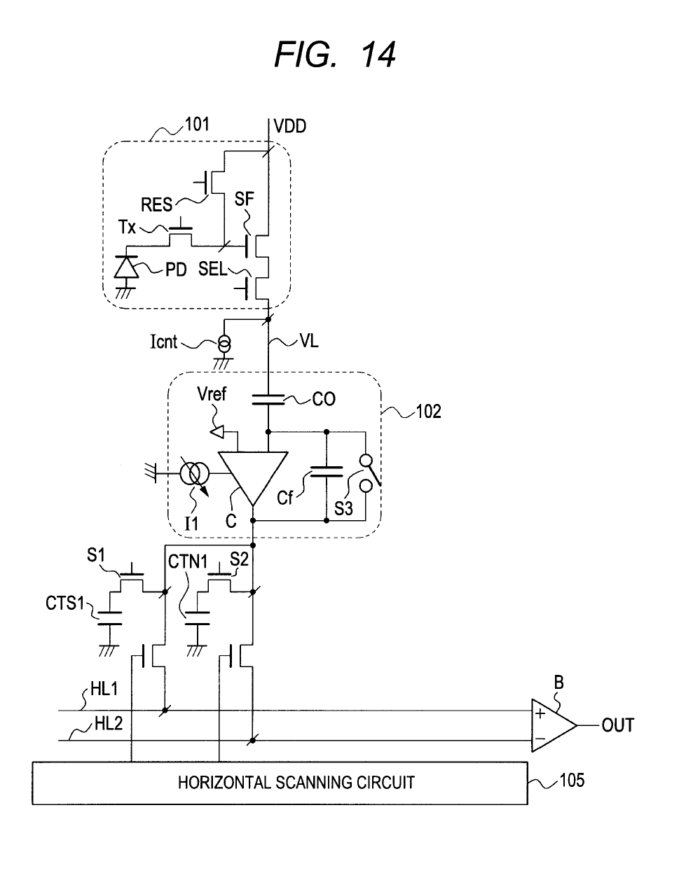

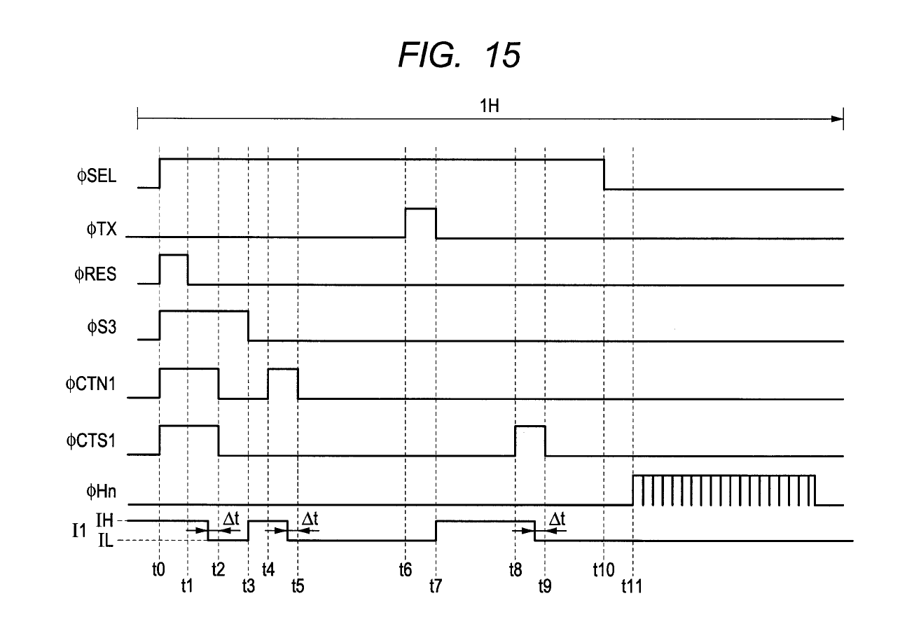

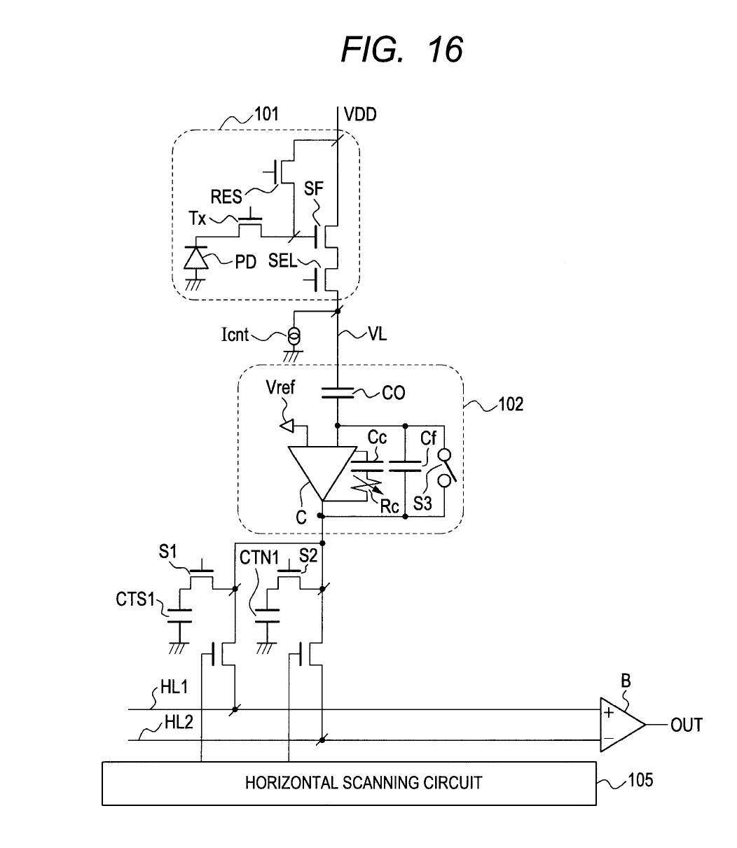

FIG. 14 is a diagram illustrating an example configuration of an imaging apparatus according to a fifth embodiment. The sampling and holding circuit according to the first embodiment is employed in a column amplifier section 102. The configuration in the Figure and an operation timing thereof will briefly be described also referring to FIG. 15. Although FIG. 14 illustrates only one pixel section 101, it should be understood that the configuration may include a plurality of pixel sections arranged in two dimensions.

The pixel 101 includes a photo diode PD, which is a photoelectric conversion element that generates a signal by means of photoelectric conversion, and a transfer portion TX that transfers a charge stored in the photo diode PD to a gate terminal of a MOS transistor included in a pixel output portion SF. The gate terminal, which is an input portion of the pixel output portion SF, is connected to a power source VDD via a reset portion RES. Furthermore, a source terminal of the pixel output portion SF is connected to one terminal of an input capacitor C0 of the column amplifier 102 via the pixel selection portion SEL and also to a constant current source Icnt.

The column amplifier 102, which includes an operational amplifier C, amplifies an output signal of the pixel 101. An inverting input terminal of the operational amplifier C is connected to another terminal of the input capacitor C0. A feedback capacitor Cf is connected between the inverting input terminal and an output terminal of the operational amplifier C. Furthermore, a switch S3 that short-circuits the inverting input terminal and the output terminal of the operational amplifier C is provided. A power supply Vref is provided to a non-inverting input terminal of the operational amplifier C. A signal output from the pixel 101 to a vertical signal line VL is amplified with a gain determined by a ratio of capacitance value of the feedback capacitor Cf connected to the feedback path of the operational amplifier C and a capacitance value of the input capacitor C0. As will be described later, noise caused by the pixel 101 is reduced in the input capacitor C0. Here, a first CDS (correlated double sampling) circuit including the input capacitor C0 and the operational amplifier C is provided.

The signal amplified by the column amplifier 102 is selectively conveyed to a holding capacitor CTS1 or CTN1 via a switch S1 or S2 and held in the holding capacitor CTS1 or CTN1. The holding capacitor CTS1 stores a signal of a charge obtained as a result of photoelectric conversion by the photo diode PD, and the holding capacitor CTN1 stores a signal of a charge resulting from the pixel output portion SF being reset. The holding capacitors CTS1 and CTN1 are connected to respective horizontal signal lines HLn (n is 1 or 2). The signals stored in the holding capacitors CTS1 and CTN1 are connected to different input terminals of a differential amplifier B via respective switches. Upon input of signals φH1, φH2, . . . from a horizontal scanning circuit 105, the signals held with the holding capacitors CTS1 and CTN1 are input to the differential amplifier B via the horizontal signal lines HLn. From the differential amplifier B, a voltage difference between the signals held with the holding capacitors CTS1 and CTN1 is output. Here, a second CDS circuit including the holding capacitors CTS1 and CTN1 and the differential amplifier B is provided. An offset caused by the column amplifier 102 is reduced by the second CDS circuit.

An operation according to the present embodiment will be described with reference to FIG. 15. FIG. 14 illustrates signals φTX, φRES, φSEL and φS3 input to the transfer portion TX, the reset portion RES, the pixel selection portion SEL and the switch S3, respectively, and where the switch is conductive when the signal is at a high level. FIG. 14 also illustrates signals φCTS1 and φCTN1 provided to switches S1 and S2 provided between the holding capacitors CTS1 and CTN1 and an output terminal of the column amplifier 102, respectively. The switches are conductive when the respective signals are at a high level.

First, at a time t0, the signals except the signals φTX and φHn transition to a high level. Upon the signal φSEL transitioning to a high level, the pixel selection portion SEL becomes conductive, and thus, the source terminal of the pixel output portion SF and the constant current source Icnt are electrically connected, thereby forming a source follower amplifier. Consequently, a voltage according to the potential of the gate terminal of the pixel output portion SF appears on the vertical signal line VL as a signal. At this timing, the signal φRES is at a high level, a voltage corresponding to a state in which the gate terminal of the pixel output portion SF has been reset appears on the vertical signal line VL. Furthermore, as a result of the signal φS3 transitioning to a high level, the inverting input terminal and the output terminal of the operational amplifier C are short-circuited, and the feedback capacitor Cf is reset. With virtual grounding of the operational amplifier C, potentials of both terminals of the feedback capacitor Cf can be regarded as the same as that of the power supply Vref. Since the signals φCTN1 and φCTS1 are at a high level, the holding capacitors CTN1 and CTS1 are reset by an output of the operational amplifier C.

At a time t1, the signal φRES transitions to a low level, and the reset state of the gate terminal of the pixel output portion SF is thereby stopped. At a time t2, the signals φS3, φCTN1 and φCTS1 transition to a low level, and the respective corresponding switches enter a non-conductive state.

Subsequently, at a time t3, the signal φS3 transitions to a low level, and the short-circuited state of the input and output terminals of the operational amplifier C is stopped. At the input capacitor C0, the level corresponding to the reset of the gate terminal of the pixel output portion SF is clamped by the power supply Vref.

With this clamping operation the noise caused by the pixel 101 may be reduced.

At a time t4, the signal φCTN1 transitions to a high level, and at a time t5, the signal φCTN1 transitions to a low level, whereby an output signal of the column amplifier 102 at this time is held in the holding capacitor CTN1. In other words, the signal held in the holding capacitor CTN1 contains an offset component caused by the column amplifier 102.

Upon the signal φTX transitioning to a high level at a time t6, a charge stored in the photo diode PD is transferred to the gate terminal of the pixel output portion SF. Consequently, the potential of the gate terminal of the pixel output portion SF changes, and thus, the voltage appearing on the vertical signal line VL also changes. At this time, the input capacitor C0 is in a floating state, and thus, only the amount of the potential change from the level of the vertical signal line VL, which has been clamped at the time t1, is input to the inverting input terminal of the operational amplifier C. Consequently, the signal resulting from the photoelectric conversion is input to the operational amplifier C.

From a time t8, the signal φCTS1 transitions to a high level, and then the signal φCTS1 transitions to a low level, whereby a signal resulting from amplification of the level appearing on the vertical signal line VL is held in the holding capacitor CTS1. Here, the signal held in the holding capacitor CTS1 contains an offset caused by the column amplifier 102 as with the holding capacitor CTN1.

Subsequently, the signal φSEL transitions to a low level, and the selected state of the pixel 101 is stopped. The signals held in the respective holding capacitors CTS1 and CTN1 each contain an offset caused by the column amplifier 102, and thus, a difference between the signals is obtained by means of the differential amplifier B, enabling reduction in the offset component.

Subsequently, the signals φHn are output from the horizontal scanning circuit 105, the signals are transferred to the horizontal signal lines HL1 and HL2 from the capacitors CTS1 and CTN1, and a signal is output from the differential amplifier (output amplifier) B.

Then, an operation according to the present embodiment will be described in relation to the aforementioned signal reading operation. The operational amplifier C corresponds to the buffer amplifier A in FIG. 1, the switches S1 and S2 correspond to the switch S in FIG. 1, and the capacitors CTS1 and CTN1 correspond to the holding capacitor Ch in FIG. 1. For high-speed, low noise storage of signals from the pixel 101 in the capacitors CTS1 and CTN1 in FIG. 14, when the column amplifier C drives the capacitors CTS1 and the CTN1, a value of a bias current source I1 in the amplifier C is changed as in the first embodiment. More specifically, in the timing diagram in FIG. 15, before each certain time at which the signal φCTS1 and/or the signal φCTN1 transition from a high level to a low level (indicated by Δt in the Figure), the current from the bias current source I1 is changed from a large current IH to a small current IL. Signal charge from the amplifier C is charged and discharged to and from the capacitors CTS1 and CTN1 at a high speed. Then, after the potentials of capacitors CTS1 and CTN1 settling to a level, the current of the bias current source I1 is reduced to the small current IL, and the amplifier C thereby drives both the capacitors CTS1 and CTN1 in a low noise mode. The time Δt in FIG. 15 is determined based on the pulse widths of the signals φCTS1 and φCTN1 in consideration of the time of settling of the amplifier C.

### Sixth Embodiment

For a method for changing the amplifier C from a high-speed mode to a low-noise mode, it should be understood that the method in which the resistor Rc connected in series with the phase compensation capacitor in the amplifier C is changed, which has been described in the second embodiment, can be employed instead of the above-described method.

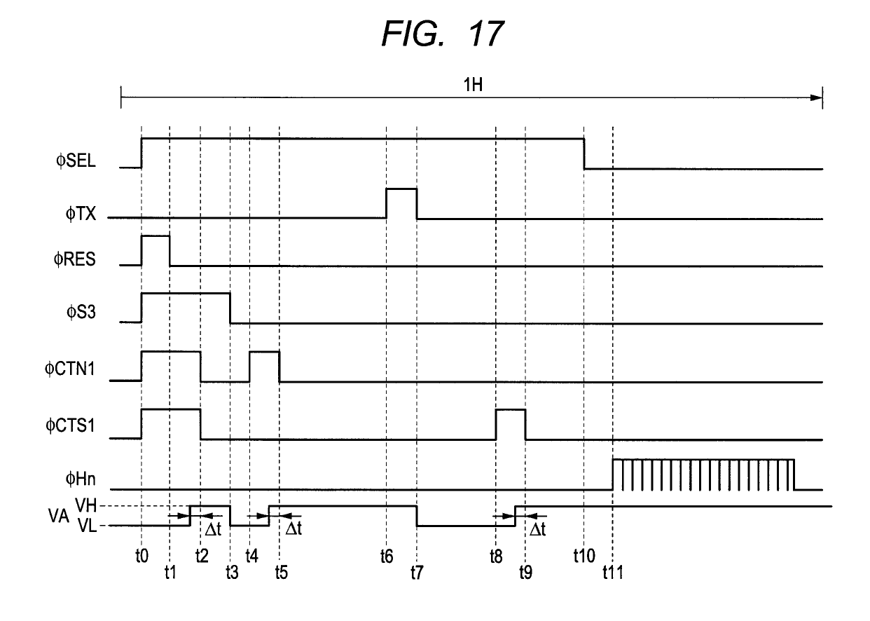

FIG. 16 is a diagram illustrating an example configuration of an imaging apparatus according to a sixth embodiment. An operational amplifier C corresponds to the buffer amplifier A in FIG. 1, switches S1 and S2 correspond to the switch S in FIG. 1, and capacitors CTS1 and CTN1 correspond to the holding capacitor Ch in FIG. 1. For an embodiment of a variable resistor Rc for the operational amplifier C, the above-described MOS transistor M6 in FIG. 11 and a pulse voltage source VA that drives the gate terminal of the MOS transistor M6 can be used. FIG. 17 illustrates timings in an operation of the imaging apparatus in FIG. 16. For reading, the timings are substantially the same as those in FIG. 15, and timings of change in the voltage of the pulse voltage source VA is indicated instead of the current source I1 in FIG. 15. In other words, in the timing diagram in FIG. 17, before each certain time at which the signal φCTS1 and/or the signal φCTN1 transition from a high level to a low level (indicated by Δt in the Figure), the voltage of the voltage source VA is changed from a certain low voltage VL to a certain high voltage VH. Consequently, signal charge from the amplifier C is charged and discharged to and from the capacitors CTS1 and CTN1 at a high speed, and after the potentials of the capacitors CTS1 and CTN1 reaching a stationary state after end of the charge and discharge, the voltage of the voltage source VA is increased to the high voltage VH, and the amplifier C thereby drives both capacitors in a low noise mode. As in the fifth and sixth embodiments, the sampling and holding circuit according to each of the third and fourth embodiments can also be employed in the column amplifier 102 in the imaging apparatus.

All of the above-described embodiments are mere specific examples for carrying out the present invention, and thus, the technical scope of the present invention should not be construed to be limited to these embodiments. In other words, the present invention can be carried out in various modes without departing from the technical idea or the main features of the present invention.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2010-185421, filed Aug. 20, 2010, which is hereby incorporated by reference herein in its entirety.

What is claimed is:

1. A sampling and holding circuit comprising:
an amplifier for amplifying a signal;
a holding capacitor for storing the signal; and
a switch connected between the amplifier and the holding capacitor, wherein
the amplifier amplifies the signal with a first signal bandwidth under a state in which the switch is on, thereafter the amplifier amplifies the signal with a second signal bandwidth under the state in which the switch is on, the second bandwidth being narrower than the first signal bandwidth, and thereafter the switch is turned off while the amplifier maintains the second signal bandwidth.

2. The sampling and holding circuit according to claim 1, wherein
the amplifier amplifies the signal with the first signal bandwidth by being supplied with a first bias current, and amplifies the signal with the second signal bandwidth by being supplied with a second bias current smaller than the first bias current.

3. The sampling and holding circuit according to claim 1, wherein
the amplifier is a negative feedback amplifier having a phase compensating circuit including a capacitor and a serially connected variable resistor, the amplifier amplifies the signal with the first signal bandwidth by setting the variable resistor at a first resistance value, and the amplifier amplifies the signal with the second signal bandwidth by setting the variable resistor at a second resistance value smaller than the first resistance value.

4. The sampling and holding circuit according to claim 3, wherein
the variable resistor is a MOS transistor, such that a resistance of the MOS transistor changes according to a gate voltage of the MOS transistor.

5. The sampling and holding circuit according to claim 1, wherein
the amplifier is a negative feedback amplifier.

6. The sampling and holding circuit according to claim 1, wherein
the amplifier is a source follower amplifier.

7. An imaging apparatus comprising:
a pixel including a photoelectric conversion element;
an amplifier for amplifying a signal from the photoelectric conversion element;
a holding capacitor for storing the signal; and
a switch connected between the amplifier and the holding capacitor, wherein
the amplifier amplifies the signal with a first signal bandwidth under a state in which the switch is on, thereafter the amplifier amplifies the signal with a second signal under the state in which the switch is on, the second bandwidth being narrower than the first signal bandwidth, and thereafter the switch is turned off while the amplifier maintains the second signal bandwidth.

8. The imaging apparatus according to claim 7, wherein
the amplifier amplifies the signal in the first signal bandwidth by being supplied with a first bias current, and amplifies the signal in the second signal bandwidth by being supplied with a second bias current smaller than the first bias current.

9. The imaging apparatus according to claim 7, wherein
the amplifier is a negative feedback amplifier having a phase compensating circuit including a serial connected circuit of a capacitor and a variable resistor, the amplifier amplifies the signal with the first signal bandwidth by setting the variable resistor at a first resistance value, and the amplifier amplifies the signal with the second signal bandwidth by setting the variable resistor at a second resistance value smaller than the first resistance value.

10. The imaging apparatus according to claim 7, wherein
the amplifier is a negative feedback amplifier.

11. A method for driving a sampling and holding circuit, wherein the sampling and holding circuit comprises:
an amplifier for amplifying a signal;
a holding capacitor for storing the signal; and
a switch connected between the amplifier and the holding capacitor, and wherein the method comprises steps of:
driving the amplifier with a first bandwidth while the switch is on;
driving the amplifier with a second bandwidth while the switch is on, the second bandwidth being narrower than the first bandwidth;
turning off the switch while driving the amplifier with the second bandwidth.

12. The method according to claim 11, wherein
driving the amplifier includes supplying a first bias current to the amplifier; and
driving the amplifier includes supplying a second bias current to the amplifier, the second bias being smaller than the first bias current.
